(19) United States
(12) Patent Application Publication
(10) Pub. No.: US 2024/0258416 A1
(43) Pub. Date: Aug. 1, 2024

(54) TRANSISTOR

(71) Applicant: Japan Display Inc., Tokyo (JP)

(72) Inventors: Hiroumi KINJO, Tokyo (JP); Masumi NISHIMURA, Tokyo (JP); Hayata AOKI, Tokyo (JP)

(73) Assignee: Japan Display Inc., Tokyo (JP)

(21) Appl. No.: 18/597,074

(22) Filed: Mar. 6, 2024

Related U.S. Application Data
(63) Continuation of application No. PCT/JP2022/029663, filed on Aug. 2, 2022.

(30) Foreign Application Priority Data
Sep. 7, 2021 (JP) 2021-145463

(51) Int. Cl. H01L 29/778; H01L 29/20

(52) U.S. Cl. CPC H01L 29/7786; H01L 29/2003

(57) ABSTRACT

A transistor according to an embodiment of the present invention includes an amorphous substrate, a conductive alignment layer over the amorphous substrate, a heterojunction structure including a semiconductor layer and a polarization layer in contact with the semiconductor layer over the conductive alignment layer, and a gate electrode over the heterojunction structure. The heterojunction structure comprises a recessed portion in a region overlapping the gate electrode. The recessed portion may be provided in the polarization layer or the semiconductor layer.

### CROSS-REFERENCE TO RELATED APPLICATIONS

This application is a Continuation of International Patent Application No. PCT/JP2022/029663, filed on Aug. 2, 2022, which claims the benefit of priority to Japanese Patent Application No. 2021-145463, filed on Sep. 7, 2021, the entire contents of which are incorporated herein by reference.

### FIELD

An embodiment of the present invention relates to a transistor using a compound semiconductor, in particular, a high electron mobility transistor (HEMT).

### BACKGROUND

Gallium nitride (GaN) is a direct bandgap semiconductor with a large bandgap. Focusing on the properties of gallium nitride, gallium nitride has the characteristics of high saturated electron mobility and a high breakdown voltage. In recent years, a transistor for a high-frequency power device, that is, a HEMT has been developed by utilizing the characteristics of gallium nitride.

The HEMT has a heterojunction structure in which not only a gallium nitride film but also an aluminum gallium nitride (AlGaN) film is provided in contact with the gallium nitride film. At the interface between the gallium nitride film and the aluminum gallium nitride film, charges are induced by the spontaneous polarization of the gallium nitride film in the semiconductor layer and the piezoelectric effect of the aluminum gallium nitride in the polarization layer, so that a high-density two-dimensional electron gas (2DEG) is formed. Since the concentration of the two-dimensional electron gas in HEMT is large and the saturated electron mobility is also high, high-speed operation in the HEMT is possible.

A gallium nitride film for a HEMT is generally formed on a sapphire substrate at a high temperature of 800 degrees to 1000 degrees using MOCVD (Metal Organic Chemical Vapor Deposition) or HVPE (Hydride Vapor Phase Epitaxy).

### SUMMARY

A transistor according to an embodiment of the present invention includes an amorphous substrate, a conductive alignment layer over the amorphous substrate, a heterojunction structure including a semiconductor layer and a polarization layer in contact with the semiconductor layer over the conductive alignment layer, and a gate electrode over the heterojunction structure. The heterojunction structure comprises a recessed portion in a region overlapping the gate electrode.

A transistor according to an embodiment of the present invention includes an amorphous substrate, a conductive alignment layer over the amorphous substrate, a heterojunction structure including a semiconductor layer and a polarization layer in contact with the semiconductor layer over the conductive alignment layer, a gate electrode over the heterojunction structure, and a p-type semiconductor layer overlapping the gate electrode and in contact with the polarization layer.

A transistor according to an embodiment of the present invention includes an amorphous substrate, a conductive alignment layer over the amorphous substrate, a semiconductor layer over the conductive alignment layer, a gate electrode over the semiconductor layer, an insulating layer covering the gate electrode, and a polarization layer covering the insulating layer and in contact with the semiconductor layer.

### BRIEF DESCRIPTION OF DRAWINGS

FIG. 1 is a schematic cross-sectional view showing a configuration of a transistor according to an embodiment of the present invention.

FIG. 2 is a schematic cross-sectional view showing a configuration of a transistor according to an embodiment of the present invention.

FIG. 3 is a schematic cross-sectional view showing a configuration of a transistor according to an embodiment of the present invention.

FIG. 4 is a schematic cross-sectional view showing a configuration of a transistor according to an embodiment of the present invention.

FIG. 5 is a schematic cross-sectional view showing a configuration of a transistor according to an embodiment of the present invention.

FIG. 6 is a schematic cross-sectional view showing a configuration of a transistor according to an embodiment of the present invention.

FIG. 7A is a schematic cross-sectional view showing a structure of a transistor according to an embodiment of the present invention.

FIG. 7B is a schematic plan view showing a configuration of a transistor according to an embodiment of the present invention.

FIG. 8 is a schematic cross-sectional view showing a configuration of a transistor according to an embodiment of the present invention.

### DESCRIPTION OF EMBODIMENTS

In general, although a gallium nitride film is deposited on a sapphire substrate at a high temperature, it is difficult to increase the area of the sapphire substrate, and therefore it is difficult to reduce manufacturing costs. Therefore, the develop of technology has been progressing to form an alignment layer, which can control a c-axis orientation of a gallium nitride film, on an amorphous substrate such as a glass substrate that is capable of having a large-area and to deposit the gallium nitride film by sputtering at a low temperature. However, since the alignment layer using a metal has conductivity, a HEMT including such a conductive alignment layer has a problem in that leakage current through the conductive alignment layer increases and voltage resistance decreases. Further, there is another problem whereby the HEMT tends to have normally-on type (depression type) characteristics.

In view of the above problems, an embodiment of the present invention can provide a transistor that includes a conductive alignment layer on an amorphous substrate and has a reduced leakage current.

Hereinafter, each of the embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification, the expressions “a includes A, B or C”, “a includes any of A, B and C”, and “a includes one selected from the group consisting of A, B and C” do not exclude the case where a includes a plurality of combinations of A to C unless otherwise specified. Further, these expressions do not exclude the case where a includes other elements.

In the specification, although the phrases “above” or “above direction” or “below” or “below direction” are used for convenience of explanation, in principle, the direction from a substrate toward a structure is referred to as “above” or “above direction” with reference to a substrate in which the structure is formed. Conversely, the direction from the structure to the substrate is referred to as “below” or “below direction”. Therefore, in the expression of a structure over a substrate, one surface of the structure in the direction facing the substrate is the bottom surface of the structure and the other surface is the upper surface of the structure. In addition, the expression of a structure over a substrate only explains the vertical relationship between the substrate and the structure, and another member may be placed between the substrate and the structure. Furthermore, the terms “above” or “above direction” or “below” or “below direction” mean the order of stacked layers in the structure in which a plurality of layers are stacked, and may not be related to the position in which layers overlap in a plan view.

In the specification, terms such as “first”, “second”, or “third” attached to each component are convenient terms used to distinguish each component, and have no further meaning unless otherwise explained.

In the specification and the drawings, the same reference numerals may be used when multiple configurations are identical or similar in general, and reference numerals with a lower or upper case letter of the alphabet may be used when the multiple configurations are distinguished. Further, reference numerals with a hyphen and a natural number may be used when multiple portions of one configuration are distinguished.

The following embodiments can be combined with each other as long as there is no technical contradiction.

### First Embodiment

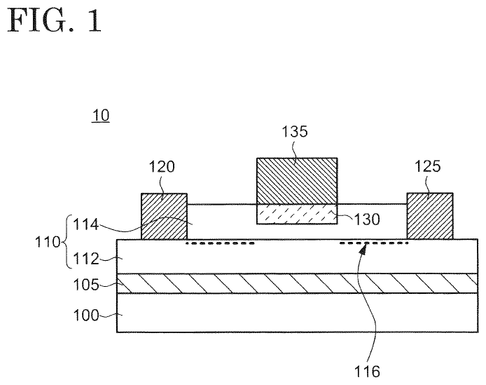

FIG. 1 is a schematic cross-sectional view showing a configuration of a transistor 10 according to an embodiment of the present invention.

As shown in FIG. 1, the transistor 10 includes an amorphous substrate 100, a conductive alignment layer 105, a heterojunction structure 110, a source electrode 120, a drain electrode 125, a gate insulating layer 130, and a gate electrode 135. The conductive alignment layer 105 is provided on the amorphous substrate 100. The heterojunction structure 110 is provided on the conductive alignment layer 105. The heterojunction structure 110 includes a semiconductor layer 112 and a polarization layer 114 in contact with the semiconductor layer 112, and the semiconductor layer 112 is in contact with the conductive alignment layer 105. The source electrode 120 and the drain electrode 125 are provided on and in contact with the semiconductor layer 112. The gate electrode 135 is provided over the polarization layer 114. The gate insulating layer 130 is provided between the polarization layer 114 and the gate electrode 135.

In the polarization layer 114 of the heterojunction structure 110, a recessed portion is provided in a region overlapping the gate electrode 135. That is, in the polarization layer 114, the thickness of the region overlapping the gate electrode 135 is smaller than the thickness of the region not overlapping the gate electrode 135. Further, the gate insulating layer 130 is provided in the recessed portion of the polarization layer 114. The gate insulating layer 130 may be provided to fill the recessed portion or may be provided to cover the recessed portion. In addition, the recessed portion can be formed by etching or the like.

The amorphous substrate 100 is a support substrate for the transistor 10 including the heterojunction structure 110. Although details are described later, since the semiconductor layer 112 and the polarization layer 114 of the heterojunction structure 110 are formed by sputtering, the amorphous substrate 100 may have heat resistance of, for example, about 600 degrees. Therefore, for example, an amorphous glass substrate can be used as the amorphous substrate 100. Further, a resin substrate such as a polyimide substrate, an acrylic substrate, a siloxane substrate, or a fluororesin substrate can also be used as the amorphous substrate 100. Such an amorphous glass substrate or resin substrate is a substrate that can be provided with a large area. In addition, a polycrystalline substrate can also be used instead of the amorphous substrate 100. In manufacturing the transistor 10, since the semiconductor layer 112 of the heterojunction structure 110 is crystal-grown on the conductive alignment layer 105, the amorphous glass substrate, the resin substrate, or the polycrystalline substrate that is larger than a sapphire substrate generally used when forming a gallium nitride film can be used as the support substrate for the transistor 10.

Although not shown in figures, the amorphous substrate 100 may be provided with a base layer. The base layer can prevent impurities from the amorphous substrate 100 or impurities from the outside (e.g., moisture, sodium (Na), etc.) from diffusing into the semiconductor layer 112. For example, a silicon nitride (SiNₓ) film or the like can be used as the base layer. Further, a laminated film of a silicon oxide (SiOₓ) film and a silicon nitride (SiNₓ) film can also be used as the base layer.

The conductive alignment layer 105 can improve the crystallinity of the semiconductor layer 112 formed on the conductive alignment layer 105. Specifically, the conductive alignment layer 105 can control so that a c-axis of a film formed on the conductive alignment layer 105 grows in the thickness direction. In other words, the conductive alignment layer 105 can control so that the semiconductor layer 112 has a c-axis orientation. For example, in the case that the semiconductor layer 112 is a gallium nitride film, although the gallium nitride film having a hexagonal close-packed structure is oriented along the c-axis so as to minimize surface energy, crystal growth of the gallium nitride film with the c-axis orientation can be promoted by depositing the gallium nitride on the alignment layer 105. A conductive material having a hexagonal close-packed structure, a face-centered cubic structure, or a structure equivalent thereto can be used for the alignment layer 105. Here, the structure equivalent to the hexagonal close-packed structure or the face-centered cubic structure includes a crystal structure in which the c-axis is not 90 degrees with respect to the a-axis and the b-axis. The alignment layer 105 with the conductive material having the hexagonal close-packed structure or the structure equivalent thereto can have an orientation in the (0001) direction, that is, in the c-axis direction with respect to the substrate 100 (hereinafter, referred to as the (0001) orientation of the hexagonal close-packed structure). Further, the alignment layer 105 with the material having the face-centered cubic structure or the structure equivalent thereto can have an orientation in the (111) direction with respect to the substrate 100 (hereinafter, referred to as the (111) orientation of the face-centered cubic structure). When the alignment layer 105 has the (0001) orientation of the hexagonal close-packed structure or the (111) orientation of the face-centered cubic structure, the crystal growth of the gallium nitride film in the c-axis direction is promoted and the semiconductor layer 112 has c-axis orientation with high crystallinity. In addition, the semiconductor layer 112 is not limited to the gallium nitride film.

The crystallinity of the semiconductor layer 112 on the conductive alignment layer 105 is affected by the surface state of the conductive alignment layer 105. Therefore, it is preferable that the conductive alignment layer 105 has a smooth surface with little unevenness. For example, the surface arithmetic mean roughness (Ra) of the conductive alignment layer 105 is preferably less than 2.3 nm. Further, the root mean square roughness (Rq) of the surface of the conductive alignment layer 105 is preferably less than 2.9 nm. When the surface roughness of the conductive alignment layer 105 satisfies the above conditions, the semiconductor layer 112 has the c-axis orientation with further high crystallinity. In addition, the thickness of the conductive alignment layer 105 is preferably greater than or equal to 50 nm.

The conductive alignment layer 105 has conductivity. For example, titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), BiLaTiO, SrFeO, BiFeO, BaFeO, ZnFeO, or PMnN-PZT, or the like can be used for the conductive alignment layer 105. In particular, it is preferable to use titanium, graphene, or zinc oxide for the conductive alignment layer 105. In addition, the conductive alignment layer 105 can be formed using any method (apparatus) such as sputtering or CVD.

The heterojunction structure 110 has a structure in which the semiconductor layer 112 containing a first compound semiconductor and the polarization layer 114 containing a second compound semiconductor different from the first compound semiconductor are in contact with each other. That is, in the heterojunction structure 110, a heterojunction having band discontinuity is formed between the first compound semiconductor and the second compound semiconductor, and a two-dimensional electron gas (2DEG) 116 with high concentration and high mobility is generated at the junction interface due to the spontaneous polarization and the piezo effect. However, as described above, in the transistor 10, the polarization layer 114 is provided with the recessed portion overlapping the gate electrode 135 and includes a region with a small thickness. Since the piezo effect weakens in this region, the concentration of the two-dimensional electron gas 116 formed in the semiconductor layer 112 decreases or disappears in the region. Therefore, leakage current between the two-dimensional electron gas 116 and the conductive alignment layer 105 can be suppressed in the region of the semiconductor layer 112 overlapping the gate electrode 135. On the other hand, in a region of the semiconductor layer 112 not overlapping the gate electrode 135 (that is, not overlapping the recessed portion of the polarization layer 114), the concentration of the two-dimensional electron gas 116 is maintained high due to the piezo effect. Therefore, in the transistor 10, the short channel effect can be reduced while suppressing the parasitic resistance of the source electrode 120 and the drain electrode 125. Further, since a channel for the two-dimensional electron gas 116 is formed when a voltage is applied to the gate electrode 135, the transistor 10 has normally-off type (enhancement type) characteristics.

For example, although the first compound semiconductor and the second compound semiconductor are gallium nitride (GaN) and aluminum gallium nitride (AlGaN) respectively, the materials of the first compound and the second compound are not limited thereto. As described above, since the semiconductor layer 112 is formed on the conductive alignment layer 105, the semiconductor layer 112 has the c-axis orientation with high crystallinity. Further, since the polarization layer 114 is formed on the semiconductor layer 112 having the c-axis orientation with high crystallinity, the polarization layer 114 also has a c-axis orientation with high crystallinity.

Here, a deposition of a gallium nitride film using sputtering is described as an example of forming the semiconductor layer 112 or the polarization layer 114.

The amorphous substrate 100 is placed facing a gallium nitride target in a vacuum chamber. It is preferable that the composition ratio of gallium nitride in the gallium nitride target is greater than or equal to 0.7 and less than or equal to 2 of gallium to nitrogen. Further, nitrogen can also be supplied to the vacuum chamber as a gas other than the sputtering gas (such as argon (Ar) or krypton (Kr)). In that case, it is preferable that the composition ratio of gallium nitride in the gallium nitride target is more gallium than nitrogen. For example, nitrogen can be supplied using a nitrogen radical source. The sputtering power supply source may be either a DC power supply source, an RF power supply source, or a pulsed DC power supply source.

The amorphous substrate 100 in the vacuum chamber may be heated. For example, the amorpous substrate 100 can be heated at a temperature greater than or equal to room temperature and less than 600 degrees, preferably greater than or equal to 100 degrees and less than or equal to 400 degrees. This temperature can be applied to an amorphous glass substrate having low heat resistance. Further, this temperature is lower than the deposition temperature in MOCVD or HVPE.

After the vacuum chamber is sufficiently evacuated, the sputtering gas is supplied to the vacuum chamber. Further, a voltage is applied between the amorphous substrate 100 and the gallium nitride target at a predetermined pressure to generate a plasma and the gallium nitride film is deposited.

Although the deposition method of the gallium nitride film by sputtering is described, the configurations or conditions of sputtering can be changed as appropriate. In addition, an aluminum gallium nitride film can be deposited by using an aluminum gallium nitride target instead of the gallium nitride target. Further, a p-type gallium nitride film (p-type semiconductor film) can be formed by using a gallium nitride target doped with magnesium.

For example, a metal such as aluminum (AI), titanium (Ti), platinum (Pt), nickel (Ni), tantalum (Ta), or gold (Au), or an alloy thereof can be used for each of the source electrode 120 and the drain electrode 125. Each of the source electrode 120 and the drain electrode 125 may be a single film or a laminated film.

Each of the source electrode 120 and the drain electrode 125 may be provided on the semiconductor layer 112 or may be embedded in the semiconductor layer 112. Further, each of the source electrode 120 and the drain electrode 125 may be provided on the polarization layer 114 or may be embedded in the polarization layer 114.

For example, silicon oxide (SiOₓ), aluminum oxide (AlOₓ), hafnium oxide (HfOₓ), lanthanum oxide (LaOₓ), silicon nitride (SiNₓ), aluminum nitride (AlNₓ) or the like can be used for the gate insulating layer 130. The gate insulating layer 130 may be a single film or a laminated film.

For example, a metal such as aluminum (AI), titanium (Ti), platinum (Pt), nickel (Ni), tantalum (Ta), or gold (Au), or an alloy thereof can be used for the gate electrode 135. The gate electrode 135 may be a single film or a laminated film.

In addition, the transistor 10 may have a structure in which the gate insulating layer 130 is not provided. In this case, the gate electrode 135 is in contact with the polarization layer 114 and functions as a so-called Schottky gate electrode.

As described above, the transistor 10 includes the heterojunction structure 110 with controlled crystallinity on the conductive alignment layer 105. Further, the polarization layer 114 of the heterojunction structure 110 includes the region with a small thickness overlapping the gate electrode 135 (the region provided with the recessed portion). Therefore, in the transistor 10, the piezoelectric effect in the region of the polarization layer 114 overlapping the gate electrode 135 is weakened, and leakage current between the two-dimensional electron gas 116 formed in the semiconductor layer 112 and the conductive alignment layer 105 can be suppressed. Furthermore, since a channel for the two-dimensional electron gas 116 is formed when a voltage is applied to the gate electrode 135, the transistor 10 has normally-off type (enhancement type) characteristics.

### Second Embodiment

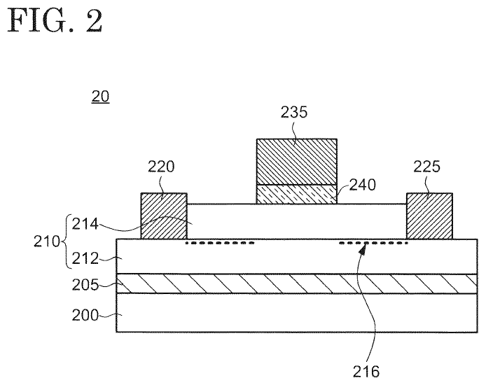

FIG. 2 is a schematic cross-sectional view showing a configuration of a transistor 20 according to an embodiment of the present invention. Hereinafter, when the configuration of the transistor 20 is similar to the configuration of the transistor 10, the description of the configuration of the transistor 20 may be omitted.

As shown in FIG. 2, the transistor 20 includes an amorphous substrate 200, a conductive alignment layer 205, a heterojunction structure 210, a source electrode 220, a drain electrode 225, a p-type semiconductor layer 240, and a gate electrode 235. The conductive alignment layer 205 is provided on the amorphous substrate 200. The heterojunction structure 210 is provided on the conductive alignment layer 205. The heterojunction structure 210 includes a semiconductor layer 212 and a polarization layer 214 in contact with the semiconductor layer 212, and the semiconductor layer 212 is in contact with the conductive alignment layer 205. The source electrode 220 and the drain electrode 225 are provided on and in contact with the semiconductor layer 212. The gate electrode 235 is provided over the polarization layer 214. The p-type semiconductor layer 240 overlaps the gate electrode 235 and is provided between the polarization layer 214 and the gate electrode 235. Further, the p-type semiconductor layer 240 is in contact with the polarization layer 214.

Since the p-type semiconductor layer 240 is in contact with the polarization layer 214, the holes in the p-type semiconductor layer 240 can reduce the polarity of the polarization layer 214 which weakens the piezo effect of the polarization layer 214. Therefore, the concentration of the two-dimensional electron gas 216 in the region of the semiconductor layer 212 overlapping the gate electrode 235 decreases or disappears. Therefore, in the region of the semiconductor layer 212 overlapping the gate electrode 235, leakage current between the two-dimensional electron gas 216 and the conductive alignment layer 205 can be suppressed. On the other hand, in a region of the semiconductor layer 212 not overlapping the p-type semiconductor layer 240, the concentration of the two-dimensional electron gas 216 is maintained high due to the piezo effect. Therefore, in the transistor 20, the short channel effect can be reduced while suppressing the parasitic resistance of the source electrode 220 and the drain electrode 225. Further, since a channel for the two-dimensional electron gas 216 is formed when a voltage is applied to the gate electrode 235, the transistor 20 has normally-off type (enhancement type) characteristics.

As described above, the transistor 20 includes the heterojunction structure 210 with controlled crystallinity on the conductive alignment layer 205. Further, the polarization layer 214 of the heterojunction structure 210 is in contact with the p-type semiconductor layer 240 overlapping the gate electrode 235. Therefore, in the transistor 20, the piezoelectric effect in the region of the polarization layer 214 overlapping the gate electrode 235 is weakened, and leakage current between the two-dimensional electron gas 216 formed in the semiconductor layer 212 and the conductive alignment layer 205 can be suppressed. Furthermore, since a channel for the two-dimensional electron gas 216 is formed when a voltage is applied to the gate electrode 235, the transistor 20 has normally-off type (enhancement type) characteristics.

### Third Embodiment

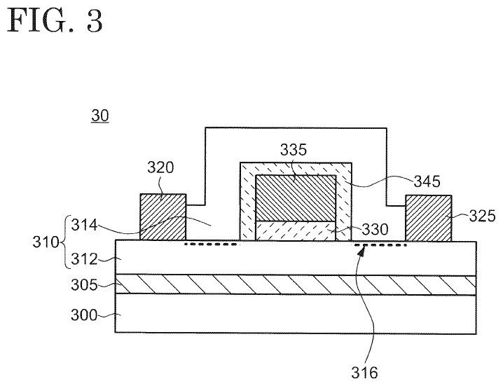

FIG. 3 is a schematic cross-sectional view showing a configuration of a transistor 30 according to an embodiment of the present invention. Hereinafter, when the configuration of the transistor 30 is similar to the configuration of the transistor 10, the description of the configuration of the transistor 30 may be omitted.

As shown in FIG. 3, the transistor 30 includes an amorphous substrate 300, a conductive alignment layer 305, a semiconductor layer 312, a source electrode 320, a drain electrode 325, a gate insulating layer 330, a gate electrode 335, an insulating layer 345, and a polarization layer 314. The conductive alignment layer 305 is provided on the amorphous substrate 300. The semiconductor layer 312 is provided on and in contact with the conductive alignment layer 305. The source electrode 320 and the drain electrode 325 are provided on and in contact with the semiconductor layer 312. The gate electrode 335 is provided over the semiconductor layer 312. The gate insulating layer 330 is provided between the semiconductor layer 312 and the gate electrode 335. The insulating layer 345 covers the gate insulating layer 330 and the gate electrode 335. The polarization layer 314 covers the insulating layer 345 and is in contact with the semiconductor layer 312 between the source electrode 320 and the drain electrode 325.

In manufacturing the transistor 30, although the polarization layer 314 is formed after the source electrode 320 and the drain electrode 325 are formed, the process of the formation of the polarization 314 is not limited thereto. The source electrode 320 and the drain electrode 325 may be formed after the polarization layer 314 is formed.

In the polarization layer 314, a region not overlapping the gate electrode 335 is in contact with the semiconductor layer 312, and a region overlapping the gate electrode 335 is not in contact with the semiconductor layer 312. Therefore, the two-dimensional electron gas 316 is not formed in the region of the semiconductor layer 312 overlapping the gate electrode 335. Therefore, leakage current between the two-dimensional electron gas 316 and the conductive alignment layer 305 can be suppressed in the region of the semiconductor layer 312 overlapping the gate electrode 335. On the other hand, in the region of the semiconductor layer 312 in contact with the polarization layer 314, the concentration of the two-dimensional electron gas 316 is maintained high due to the piezo effect. Therefore, in the transistor 30, the short channel effect can be reduced while suppressing the parasitic resistance of the source electrode 320 and the drain electrode 325. Further, since, a channel for the two-dimensional electron gas 316 is formed when a voltage is applied to the gate electrode 335, the transistor 30 has normally-off type (enhancement type) characteristics.

The insulating layer 345 can function not only as a protective film for the gate insulating layer 330 and the gate electrode 335 but also as a base film for the polarization layer 314. For example, silicon oxide (SiOₓ), aluminum oxide (AlOₓ), hafnium oxide (HfOₓ), lanthanum oxide (LaOₓ), silicon nitride (SiNₓ), aluminum nitride (AlNₓ), or the like can be used for the insulating layer 345. The insulating layer 345 may be a single film or a laminated film.

In addition, the transistor 30 may have a structure in which the insulating layer 345 is not provided. In this case, since the source electrode 320, the drain electrode 325, and the gate electrode 335 can be formed by processing one film, the manufacturing process can be shortened and the manufacturing cost can be suppressed.

As described above, the transistor 30 includes the heterojunction structure 310 with controlled crystallinity on the conductive alignment layer 305. Further, the region of the semiconductor layer 312 overlapping the gate electrode 335 is not in contact with the polarization layer 314. Therefore, in the transistor 30, the formation of the two-dimensional electron gas 316 in the region of the semiconductor layer 312 overlapping the gate electrode 335 is suppressed, and leakage current between the two-dimensional electron gas 316 and the conductive alignment layer 305 can be suppressed. Furthermore, since a channel for the two-dimensional electron gas 316 is formed when a voltage is applied to the gate electrode 335, the transistor 30 has normally-off type (enhancement type) characteristics.

### Fourth Embodiment

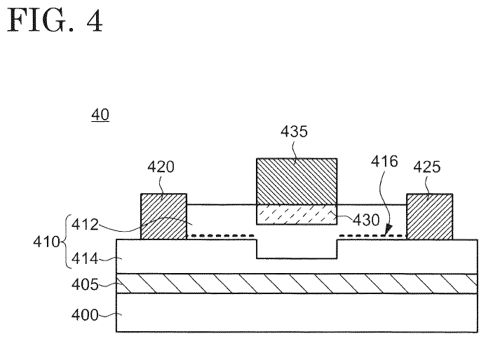

FIG. 4 is a schematic cross-sectional view showing a configuration of a transistor 40 according to an embodiment of the present invention. Hereinafter, when the configuration of the transistor 40 is similar to the configuration of the transistor 10, the description of the configuration of the transistor 40 may be omitted.

As shown in FIG. 4, the transistor 40 includes an amorphous substrate 400, a conductive alignment layer 405, a heterojunction structure 410, a source electrode 420, a drain electrode 425, a gate insulating layer 430, and a gate electrode 435. The conductive alignment layer 405 is provided on the amorphous substrate 400. The heterojunction structure 410 is provided on the conductive alignment layer 405. The heterojunction structure 410 includes a semiconductor layer 412 and a polarization layer 414 in contact with the semiconductor layer 412, and the polarization layer 414 is in contact with the conductive alignment layer 405. The source electrode 420 and the drain electrode 425 are provided on and in contact with the polarization layer 414. Further, the source electrode 420 and the drain electrode 425 are also in contact with the semiconductor layer 412. The gate electrode 435 is provided over the semiconductor layer 412. The gate insulating layer 430 is provided between the semiconductor layer 412 and the gate electrode 435.

In the polarization layer 414 of the heterojunction structure 410, a recessed portion is provided in a region overlapping the gate electrode 435. That is, in the polarization layer 414, the thickness of the region overlapping the gate electrode 435 is smaller than the thickness of a region not overlapping the gate electrode 435. Further, the semiconductor layer 412 is provided to cover the recessed portion of the polarization layer 414.

In the semiconductor layer 412 of the heterojunction structure 410, a recessed portion is provided in a region overlapping the gate electrode 435. However, the recessed portion in the semiconductor layer 412 is formed by covering the recessed portion in the polarization layer 414. Therefore, in the semiconductor layer 412, the thickness of the region overlapping the gate electrode 435 may be approximately the same as the thickness of the region not overlapping the gate electrode 435. Further, the gate insulating layer 430 is provided in the recessed portion of the semiconductor layer 412. The gate insulating layer 430 may be provided so as to partially fill the recessed portion, or may be provided so as to cover the recessed portion.

In the transistor 40, the polarization layer 414 is located between the semiconductor layer 412 in which a two-dimensional electron gas 416 is formed and the conductive alignment layer 405. Since the polarization layer 414 is an insulator, the polarization layer 414 has higher voltage resistance than the semiconductor layer 412. Further, in the heterojunction structure 410, since the polarization layer 414 includes the recessed portion with a small thickness and the piezoelectric effect is weakened in the recessed portion, the concentration of the two-dimensional electron gas 416 formed in the region of the semiconductor layer 412 overlapping the gate electrode 435 decreases or disappears. Therefore, in the transistor 40, leakage current between the two-dimensional electron gas 416 and the conductive alignment layer 405 can be suppressed.

As described above, the transistor 40 includes the heterojunction structure 410 with controlled crystallinity on the conductive alignment layer 405. Further, the transistor 40 includes the polarization layer 414 with high voltage resistance between the semiconductor layer 412 and the conductive alignment layer 405. Therefore, in the transistor 40, not only leakage current between the two-dimensional electron gas 416 and the conductive alignment layer 405 but also leakage current between the source electrode 420 or the drain electrode 425 and the conductive alignment layer 405 can be suppressed. Further, since a channel for the two-dimensional electron gas 416 is formed when a voltage is applied to the gate electrode 435, the transistor 40 has normally-off type (enhancement type) characteristics.

### Fifth Embodiment

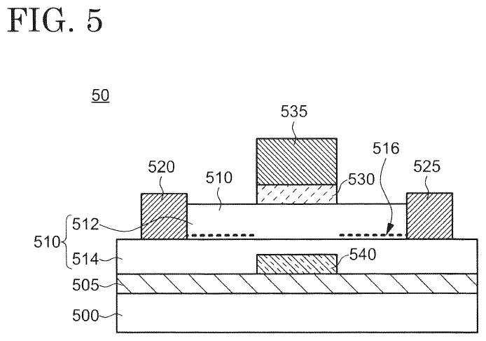

FIG. 5 is a schematic cross-sectional view showing a configuration of a transistor 50 according to an embodiment of the present invention. Hereinafter, when the configuration of the transistor 50 is similar to the configuration of the transistor 20, the description of the configuration of the transistor 50 may be omitted.

As shown in FIG. 5, the transistor 50 includes an amorphous substrate 500, a conductive alignment layer 505, a p-type semiconductor layer 540, a heterojunction structure 510, a source electrode 520, a drain electrode 525, a gate insulating layer 530, and a gate electrode 535. The conductive alignment layer 505 is provided on the amorphous substrate 500. The p-type semiconductor layer 540 overlaps the gate electrode 535 and is provided on the conductive alignment layer 505. The heterojunction structure 510 covers the p-type semiconductor layer 540 and is provided on the conductive alignment layer 505. The heterojunction structure 510 includes a semiconductor layer 512 and a polarization layer 514 in contact with the semiconductor layer 512, and the polarization layer 514 is in contact with the p-type semiconductor layer 540 and the conductive alignment layer 505. The source electrode 520 and the drain electrode 525 are provided on and in contact with the polarization layer 514. Further, the source electrode 520 and the drain electrode 525 are also in contact with the semiconductor layer 512. The gate electrode 535 is provided over the semiconductor layer 512. The gate insulating layer 530 is provided between the semiconductor layer 512 and the gate electrode 535.

In the transistor 50, the p-type semiconductor layer 540 is provided overlapping the gate electrode 535 and in contact with the polarization layer 514. Therefore, the concentration of the two-dimensional electron gas 516 in a region of the semiconductor layer 512 overlapping the gate electrode 535 decreases or disappears. Therefore, leakage current between the two-dimensional electron gas 516 and the conductive alignment layer 505 can be suppressed in the region of the semiconductor layer 512 overlapping the gate electrode 535. Further, in the transistor 50, the polarization layer 514 is located between the semiconductor layer 512 in which the two-dimensional electron gas 516 is formed and the conductive alignment layer 505. Since the polarization layer 514 is an insulator, the polarization layer 514 has higher voltage resistance than the semiconductor layer 512. Therefore, in the transistor 50, leakage current between the two-dimensional electron gas 516 and the conductive alignment layer 505 can be suppressed.

As described above, the transistor 50 includes the heterojunction structure 510 with controlled crystallinity on the conductive alignment layer 505. Further, the polarization layer 514 of the heterojunction structure 510 is in contact with the p-type semiconductor layer 540 overlapping the gate electrode 535. Therefore, in the transistor 50, the piezoelectric effect in the region of the polarization layer 514 overlapping the gate electrode 535 is weakened, and leakage current between the two-dimensional electron gas 516 formed in the semiconductor layer 512 and the conductive alignment layer 505 can be suppressed. Furthermore, since a channel for the two-dimensional electron gas 516 is formed when a voltage is applied to the gate electrode 535, the transistor 50 has normally-off type (enhancement type) characteristics. Moreover, the transistor 50 includes the polarization layer 514 with high voltage resistance between the semiconductor layer 512 and the conductive alignment layer 505. Therefore, in the transistor 50, not only leakage current between the two-dimensional electron gas 516 and the conductive alignment layer 505 but also leakage current between the source electrode 520 or the drain electrode 525 and the conductive alignment layer 505 can be suppressed.

### Sixth Embodiment

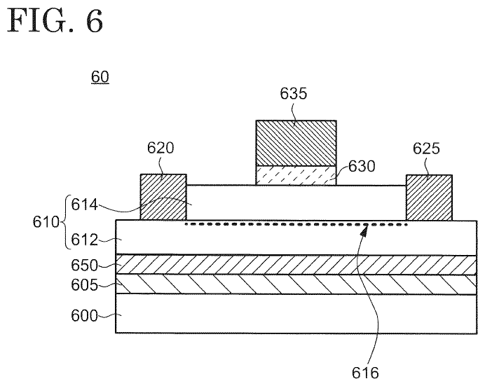

FIG. 6 is a schematic cross-sectional view showing a configuration of a transistor 60 according to an embodiment of the present invention. Hereinafter, when the configuration of the transistor 60 is similar to the configuration of the transistor 10, the description of the configuration of the transistor 60 may be omitted.

As shown in FIG. 6, the transistor 60 includes an amorphous substrate 600, a conductive alignment layer 605, a crystalline insulating layer 650, a heterojunction structure 610, a source electrode 620, a drain electrode 625, a gate insulating layer 630, and a gate electrode 635. The conductive alignment layer 605 is provided on the amorphous substrate 600. The crystalline insulating layer 650 is provided on the conductive alignment layer 605. The heterojunction structure 610 is provided on the crystalline insulating layer 650. The heterojunction structure 610 includes a semiconductor layer 612 and a polarization layer 614 in contact with the semiconductor layer 612, and the semiconductor layer 612 is in contact with the crystalline insulating layer 650. The source electrode 620 and the drain electrode 625 are provided on and in contact with the semiconductor layer 612. The gate electrode 635 is provided over the polarization layer 614. The gate insulating layer 630 is provided between the polarization layer 614 and the gate electrode 635.

The crystalline insulating layer 650 can electrically insulate the conductive alignment layer 605 and the semiconductor layer 612. By providing the crystalline insulating layer 650 between the conductive alignment layer 605 and the semiconductor layer 612, leakage current between the two-dimensional electron gas 616 formed in the semiconductor layer 612 and the conductive alignment layer 605 can be suppressed. Further, since the crystalline insulating layer 650 functions as a base film for the semiconductor layer 612, it is preferable that the crystalline insulating layer 650 has a crystal structure that does not inhibit crystal growth of the semiconductor layer 612. For example, aluminum nitride (AlNₓ), aluminum oxide (AlOₓ), gallium oxide (GaOₓ), or the like can be used for the crystalline insulating layer 650.

As described above, the transistor 60 includes the crystalline insulating layer 650 that does not inhibit crystal growth of the semiconductor layer 612 between the conductive alignment layer 605 and the semiconductor layer 612. Therefore, in the transistor 60, leakage current between the two-dimensional electron gas 616 formed in the semiconductor layer 612 and the conductive alignment layer 605 can be suppressed.

### Seventh Embodiment

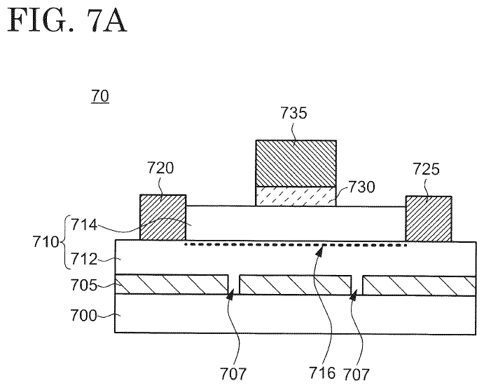

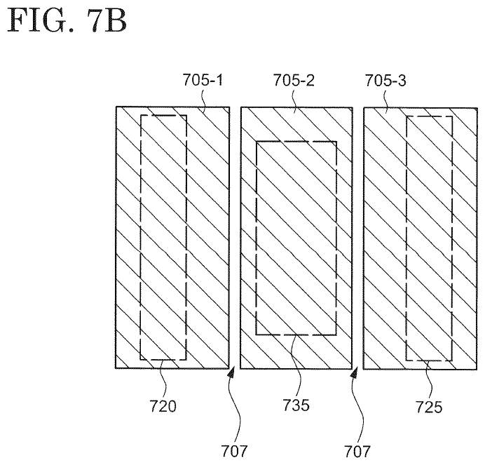

FIG. 7A and FIG. 7B are a schematic cross-sectional view and a plan view respectively showing a configuration of a transistor 70 according to an embodiment of the present invention. In FIG. 7B, a part of the configuration of the transistor 70 is shown for convenience. Hereinafter, when the configuration of the transistor 70 is similar to the configuration of the transistor 10, the description of the configuration of the transistor 70 may be omitted.

As shown in FIG. 7A, the transistor 70 includes an amorphous substrate 700, a conductive alignment layer 705, a heterojunction structure 710, a source electrode 720, a drain electrode 725, a gate insulating layer 730, and a gate electrode 735. The conductive alignment layer 705 is provided on the amorphous substrate 700. The heterojunction structure 710 is provided on the conductive alignment layer 705. The heterojunction structure 710 includes a semiconductor layer 712 and a polarization layer 714 in contact with the semiconductor layer 712, and the semiconductor layer 712 is in contact with the conductive alignment layer 705. The source electrode 720 and the drain electrode 725 are provided on and in contact with the semiconductor layer 712. The gate electrode 735 is provided over the polarization layer 714. The gate insulating layer 730 is provided between the polarization layer 714 and the gate electrode 735.

As shown in FIG. 7B, the conductive alignment layer 705 is divided into a plurality of parts by a groove portion 707. That is, in a plan view, the groove portions 707 are provided between the source electrode 720 and the gate electrode 735 and between the gate electrode 735 and the drain electrode 725, and the conductive alignment layer 705 is divided into a first conductive alignment layer 705-1, a second conductive alignment layer 705-2, and a third conductive alignment layer 705-3. Specifically, the first conductive alignment layer 705-1 overlaps the source electrode 720. The second conductive alignment layer 705-2 overlaps the gate electrode 735. The third conductive alignment layer 705-3 overlaps the drain electrode 725. Further, the first conductive alignment layer 705-1, the second conductive alignment layer 705-2, and the third conductive alignment layer 705-3 are electrically insulated from each other. Therefore, even when leakage current occurs between the two-dimensional electron gas 716 formed in a region of the semiconductor layer 712 overlapping the gate electrode 735 and the conductive alignment layer 705, the leakage current is not electrically connected to the source electrode 720 or the drain electrode 725. That is, in the transistor 70, leakage current between the source electrode 720 and the drain electrode 725 through the conductive alignment layer 705 is suppressed.

In addition, the number of divisions of the conductive alignment layer 705 is not limited to three. However, it is preferable that the number of divisions of the conductive alignment layer 705 is greater than or equal to three so that leakage current between the source electrode 720, the gate electrode 735, or the drain electrode 725 and the conductive alignment layer 705 can be separated. Further, the shape of the conductive alignment layer 705 may be a band shape extending in one direction, or a rectangular shape partitioned into a grid pattern.

As described above, in the transistor 70, since the conductive alignment layer 705 is divided, leakage current between the source electrode 720 and the drain electrode 725 through the conductive alignment layer 705 is suppressed. Further, since the conductive alignment layer 705 is divided, the parasitic capacitance caused by the conductive alignment layer 705 can be reduced.

### Eighth Embodiment

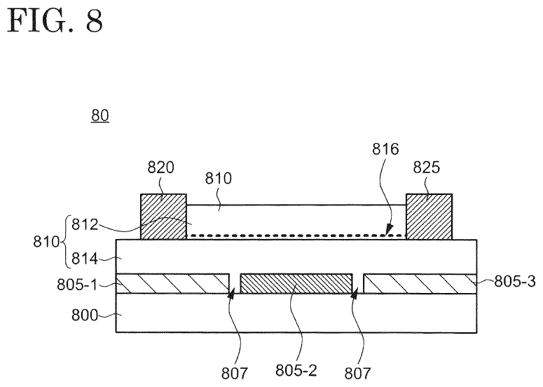

FIG. 8 is a schematic cross-sectional view showing a configuration of a transistor 80 according to an embodiment of the present invention. Hereinafter, when the configuration of the transistor 80 is similar to the configuration of the transistor 70, the description of the configuration of the transistor 80 may be omitted.

As shown in FIG. 8, the transistor 80 includes an amorphous substrate 800, a first conductive alignment layer 805-1, a second conductive alignment layer 805-2, a third conductive alignment layer 805-3, a heterojunction structure 810, a source electrode 820, and a drain electrode 825. The first conductive alignment layer 805-1, the second conductive alignment layer 805-2, and the third conductive alignment layer 805-3 are provided on the amorphous substrate 800. The heterojunction structure 810 is provided on the first conductive alignment layer 805-1, the second conductive alignment layer 805-2, and the third conductive alignment layer 805-3. The heterojunction structure 810 includes a semiconductor layer 812 and a polarization layer 814 in contact with the semiconductor layer 812, and the polarization layer 814 is in contact with the conductive alignment layer 805. The source electrode 820 and the drain electrode 825 are provided on the polarization layer 814. Further, the source electrode and drain electrode 825 are in contact with the semiconductor layer 812.

Groove portions 807 are provided between the first conductive alignment layer 805-1 and the second conductive alignment layer 805-2 and between the second conductive alignment layer 805-2 and the third conductive alignment layer 805-3. In other words, the conductive alignment layer 805 is divided into three parts. Further, the first conductive alignment layer 805-1, the second conductive alignment layer 805-2, and the third conductive alignment layer 805-3 are electrically insulated from each other. Although the transistor 80 does not have a gate electrode, the second conductive alignment layer 805-2 functions as the gate electrode. That is, when a voltage is applied to the second conductive alignment layer 805-2, a two-dimensional electron gas 816 is formed in the semiconductor layer 812.

As described above, in the transistor 80, since the conductive alignment layer 805 is divided, leakage current between the source electrode 820 and the drain electrode 825 through the conductive alignment layer 805 is suppressed. Further, since the conductive alignment layer 805 is divided, the parasitic capacitance caused by the conductive alignment layer 805 can be reduced. Furthermore, since the second conductive alignment layer 805-2, which is one of the divided conductive alignment layers 805, functions as a gate electrode, it is not necessary to provide another gate electrode. Moreover, the transistor 80 includes the heterojunction structure 810 with controlled crystallinity on the conductive alignment layer 805. Further, the transistor 80 includes the polarization layer 814 with high voltage resistance between the semiconductor layer 812 and the conductive alignment layer 805. Therefore, in the transistor 80, not only leakage current between the two-dimensional electron gas 816 and the conductive alignment layer 805 but also leakage current between the source electrode 820 and the first conductive alignment layer 805-1 and leakage current between the drain electrode 825 and the third conductive alignment layer 805-3 can be suppressed.

Each of the embodiments described above as an embodiment of the present invention can be appropriately combined and implemented as long as they do not contradict each other. Additions, deletions, or design changes of constituent elements, or additions, omissions, or changes to conditions of steps as appropriate based on the respective embodiments are also included within the scope of the present invention as long as the gist of the present invention is provided.

Other effects which differ from those brought about by each of the embodiments described above, but which are apparent from the description herein or which can be readily predicted by those skilled in the art, are naturally understood to be brought about by the present invention.

What is claimed is:

1. A transistor comprising:
an amorphous substrate;
a conductive alignment layer over the amorphous substrate;
a heterojunction structure comprising a semiconductor layer and a polarization layer in contact with the semiconductor layer, over the conductive alignment layer; and
a gate electrode over the heterojunction structure,
wherein the heterojunction structure comprises a recessed portion in a region overlapping the gate electrode.

2. The transistor according to claim 1, wherein a gate insulating layer is provided in the recessed portion.

3. The transistor according to claim 1, wherein the recessed portion is provided in the polarization layer.

4. The transistor according to claim 1, wherein the recessed portion is provided in the semiconductor layer.

5. The transistor according to claim 1, further comprising a crystalline insulating layer between the conductive alignment layer and the heterojunction structure.

6. The transistor according to claim 1, wherein the conductive alignment layer is separated into a plurality of parts.

7. The transistor according to claim 1, wherein the conductive alignment layer comprises at least one selected from titanium, graphene, and zinc oxide.

8. The transistor according to claim 1, wherein the amorphous substrate is an amorphous glass substrate.

9. A transistor comprising:
an amorphous substrate;
a conductive alignment layer over the amorphous substrate;
a heterojunction structure comprising a semiconductor layer and a polarization layer in contact with the semiconductor layer, over the conductive alignment layer;
a gate electrode over the heterojunction structure; and
a p-type semiconductor layer overlapping the gate electrode and in contact with the polarization layer.

10. The transistor according to claim 9, wherein the p-type semiconductor layer is provided between the gate electrode and the polarization layer.

11. The transistor according to claim 9, wherein the p-type semiconductor layer is provided between the conductive alignment layer and the polarization layer.

12. The transistor according to claim 9, further comprising a crystalline insulating layer between the conductive alignment layer and the heterojunction structure.

13. The transistor according to claim 9, wherein the conductive alignment layer is divided into a plurality of parts.

14. The transistor according to claim 9, wherein the conductive alignment layer comprises at least one selected from titanium, graphene, and zinc oxide.

15. The transistor according to claim 9, wherein the amorphous substrate is an amorphous glass substrate.

16. A transistor comprising:
an amorphous substrate;
a conductive alignment layer over the amorphous substrate;
a semiconductor layer over the conductive alignment layer;
a gate electrode over the semiconductor layer;
an insulating layer covering the gate electrode; and
a polarization layer covering the insulating layer and in contact with the semiconductor layer.

17. The transistor according to claim 16, wherein the conductive alignment layer is divided into a plurality of parts.

18. The transistor according to claim 16,
wherein the semiconductor layer comprises gallium nitride, and
the polarization layer comprises aluminum gallium nitride.

19. The transistor according to claim 16, wherein the conductive alignment layer comprises at least one selected from titanium, graphene, and zinc oxide.

20. The transistor according to claim 16, wherein the amorphous substrate is an amorphous glass substrate.
